(19) United States
(12) Patent Application Publication
(10) Pub. No.: US 2017/0162725 A1
(43) Pub. Date: Jun. 8, 2017

(54) SOLAR CELL

(71) Applicant: MEYER BURGER (GERMANY) AG, HOHENSTEIN-ERNSTTHAL (DE)

(72) Inventors: BENJAMIN STRAHM, GIEZ (CH); BORIS LEGRADIC, YVERDON-LES BAINS (CH); JEROME MEIXENBERGER, DIESSE (CH); DAMIEN LACHENAL, BEVAIX (CH); PIERRE PAPET, HAUTERIVE (CH)

(73) Assignee: MEYER BURGER (GERMANY) AG, HOHENSTEIN-ERNSTTHAL (DE)

(21) Appl. No.: 15/323,492

(22) PCT Filed: Jun. 30, 2015
(86) PCT No.: PCT/IB2015/054895

§ 371 Date: Jan. 3, 2017

(30) Foreign Application Priority Data
Jul. 1, 2014 (EP) 14175329.3

(51) Int. Cl. H01L 31/0216; H01L 31/0224; H01L 31/0747

(52) U.S. Cl. CPC H01L 31/02168; H01L 31/02167; H01L 31/0747; H01L 31/022466

(57) ABSTRACT

A solar cell includes a front side for light incidence, an opposite back side, a crystalline semiconductor substrate of a first or second conductivity type, a front side passivating region with a passivating layer and a conductive layer of the first type, a back side passivating region with a passivating layer and a conductive layer of the second type, a front side contact with one front side conductive material and front side electrical contacts on the front side conductive material, a front side light coupling layer on the front side, a back side contact opposite the front side contact and formed by back side conductive material and a back side electrical contact thereon. The front side has lower light absorption and better antireflective property. The front side conductive material is thinner in regions between and/or besides front side electrical contacts than in regions below front side electrical contacts.

The present invention relates to a solar cell having a front or sunny side for light incidence and a back side opposite to the front side, said solar cell comprising: a crystalline semiconductor substrate of a first conductivity type or a second conductivity type being opposite to the first conductivity type; a front side passivating region formed by at least one passivating layer and at least one conductive layer of the first conductivity type; a back side passivating region formed by at least one passivating layer and at least one conductive layer of the second conductivity type; a front side contact formed by only one front side conductive material and by front side electrical contacts formed on top of the front side conductive material; at least one front side light coupling layer on the front side of the solar cell; a back side contact being opposite the front side contact and being formed by a back side conductive material and at least one back side electrical contact formed thereon.

A solar cell of the mentioned type is known, for instance, from the document EP 2 662 900 A1. Such solar cells are generally called as silicon hetero junction solar cells. The solar cell described in the document EP 2 662 900 A1 comprises at its front side, on a single crystal silicon substrate of n-type, a layer stack of an intrinsic thin film of i-type amorphous silicon, an amorphous thin film of conductive p-type silicon, one thin transparent conductive oxide layer (TCO) of indium tin oxide (ITO), an insulating layer of, for instance, silicon nitride and a collecting electrode structure being electrically connected to the TCO layer laying by an electric pathway created through the insulating layer. By the transparent conductive oxide layer of the known solar cell, the charge carriers generated in the space charge region between the silicon substrate and the amorphous conductive silicon thin film are collected and transferred to the collecting electrode structure of the solar cell. The electrical conductivity of the transparent oxide layer is, therefore, indispensible. A major drawback of the TCO layer at the front side of the known solar cell is, however, that it absorbs part of the incoming light and does not serve as perfect anti-reflective coating for the solar cell as the insulating layer provided on top of the TCO layer does.

The document EP 2 669 952 A1 discloses a crystalline heterojunction solar cell having a front side emitter and a stack of at least two transparent conductive layers (TCO layers) formed on the emitter to enhance the efficiency of the solar cell in comparison to solar cells with only one front TCO layer. The stack of TCO layers consists of a combination of highly transparent and highly conductive materials in order to increase on the one hand with one kind of TCO material the current density and to decrease on the other hand with another kind of TCO material the contact resistance with the front metallization.

It is therefore the object of the present invention to provide a solar cell of the above mentioned type with a lower light absorption and better anti-reflective property at its front or sunny side.

This object is solved by a solar cell of the above mentioned type, wherein the front side conductive material is thinner in regions between and/or besides the front side electrical contacts than in regions below the front side electrical contacts. In comparison to the solar cell of EP 2 669 952 A1, the front side conductive material of the solar cell of the present invention is formed from only one layer and consists of only one material.

The present invention proposes to omit or to remove, at least partially, the front side conductive material in the regions between and/or besides the front side electrical contacts, that is in those regions where the front side conductive material does not serve as direct electrical “bridge” between the conductive layer of the front side passivating region and the front side electrical contacts of the solar cell. This structure has the advantage that although there is a good electrical connection between the front side passivating region and the front side electrical contacts by the conductive material formed there between, there is lower light absorption in the regions between and/or besides the front side electrical contacts due to the omitted conductive material. Moreover, the lower the thickness of the conductive material in the regions between and/or besides the front side electrical contacts, the more predominantly the anti-reflective property of the solar cell is determined in these regions by the material properties of the at least one light coupling layer. For instance, said at least one light coupling layer can be an electrically insulating layer such as a silicon nitride layer resulting in a very low light reflection. On the light incident side the light coupling layer might also be referred to as antireflective layer.

The reduction of parasitic absorption and reflection of photons with the solar cell of the present invention leads to a significant increase of the photo-generated current and, therefore, of the final output power of the solar cell and of solar cell modules manufactured on the base of the solar cell of the present invention. Moreover, the present invention allows a substitution of expensive transparent conductive material, such as indium based transparent conductive oxide, by low cost dielectric(s) such as silicon nitride (SiNₓ). Accordingly, with the present invention the cell manufacturing costs can be decreased.

In the new cell structure of the solar cell of the present invention with reduced thickness of the front side conductive material, the lateral transport of photo-generated carriers can be pushed into the bulk material of the crystalline semiconductor substrate rather than in the front side conductive material without electrical collection losses since the surface recombination velocity of crystalline semiconductor substrates produced with contemporary standards is very low. Therefore, the solar cell of the present invention is especially well adapted to cells where the emitter, such as a boron doped amorphous silicon layer, is placed at the back side of the silicon hetero junction cell when an n-type semiconductor substrate is used.

In a favorable embodiment of the present invention, the front side conductive material is absent in the regions between and/or besides the front side electrical contacts and only located in the regions below the front side electrical contacts. In that embodiment, the anti-reflective characteristics of the solar cell in the regions between and/or besides the front side electrical contacts are only determined by the material properties of the at least one light coupling layer, since the conductive material is fully omitted in these regions. The conductive material is only present directly between the conductive layer of the front side passivating region and the front side electrical contacts, which regions cover a much smaller area than the regions between and/or besides the front side electrical contacts. This leads to the effect that the solar cell can be provided with nearly perfect anti-reflection properties. In addition, in said embodiment, the light absorption can be minimized in the regions between and/or besides the front side electrical contacts, too.

In a preferred embodiment of the present invention, the emitter of the solar cell is at its back side, to say, at the shadow side of the solar cell.

In an advantageous embodiment of the present invention, the back side conductive material is only one material and has a locally increased thickness in regions, wherein at least one back side light coupling layer is provided only between these regions of increased thickness. That is, that in embodiments of the present invention in which the at least one back side electrical contact comprises a pattern of back side electrical contacts, the back side conductive material is thinner in regions between and/or besides the back side electrical contacts than in regions below the back side electrical contacts. In this embodiment of the invention, the bad influence of the back side conductive material on the anti-reflection properties of the solar cell is decreased by replacing at least a part of the back side conductive material by the at least one back side light coupling layer. In this embodiment, the effects described above with reference to the front side of the solar cell are also applied on its back side.

The anti-reflective properties of the solar cell of the present invention can be further increased if, in a specific variant of the above mentioned embodiment of the invention, the back side conductive material is not provided under the at least one back side light coupling layer. That is, that in embodiments of the invention in which the at least one back side electrical contact comprises a pattern of back side electrical contacts and at least one back side light coupling layer is formed on the back side of the solar cell, the back side conductive material is absent between the back side electrical contacts and only located in the regions below the back side electrical contacts.

A further enhancement of the current gain of the solar cell of the present invention can be achieved if, in another embodiment of the invention, the at least one conductive layer is thinner in regions between and/or besides the front side electrical contacts than in regions below the front side electrical contacts; and/or the at least one conductive layer is thinner in regions between and/or besides the back side electrical contacts than in regions below the back side electrical contacts; and/or the at least one conductive layer is thinner in regions between and/or besides regions of locally increased thickness of the side conductive material than in regions below said regions of locally increased thickness.

Favorably, but not unconditionally, the material of the at least one front side light coupling layer and/or the material of the at least one back side light coupling layer is chosen from at least one material of a group of materials comprising SiNₓ, SiOₓ, SiOₓN_{y}, AlOₓ, AlNₓ, TiOₓ, MgFₓ, a conductive oxide, a layer containing nanoparticles, or a combination of at least two of said materials.

Further favorably, but not unconditionally, the material of the front side electrical contacts and/or the material of the back side electrical contacts comprises at least one electrical conductive oxide, at least one metal, at least one metallic alloy, at least one of a conductive compound or a combination of at least two of said conductive materials.

Besides the advantages mentioned above, the present invention offers the possibility to select a more appropriate material for forming the conductive material between the conductive layer of the passivating region and the front or the back side contact, that is, the metallization of the solar cell. For instance, the front side conductive material and/or the back side conductive material can be a metal, a metal alloy or a transparent conductive oxide. The front side conductive material and/or the back side conductive material can be applied by physical vapor deposition, chemical vapor deposition, an ink-jet technology or a screen printing technology or by another suitable method.

In an optional embodiment of the present invention, the front side conductive material and/or the back side conductive material in regions between and/or besides the front side electrical contacts and/or the back side electrical contacts has a thickness between 0 and 150 nm.

According to a particular embodiment of the present invention, the front side conductive material and/or the back side conductive material in regions between and/or besides the front side electrical contacts and/or the back side electrical contacts has a thickness between 0 and 70 nm.

In an especial embodiment of the present invention, the front side conductive material and/or the back side conductive material in regions between and/or besides the front side electrical contacts and/or the back side electrical contacts has a thickness between 0 and 30 nm.

Preferred embodiments of the present invention, their structure and advantages are shown in the figures wherein

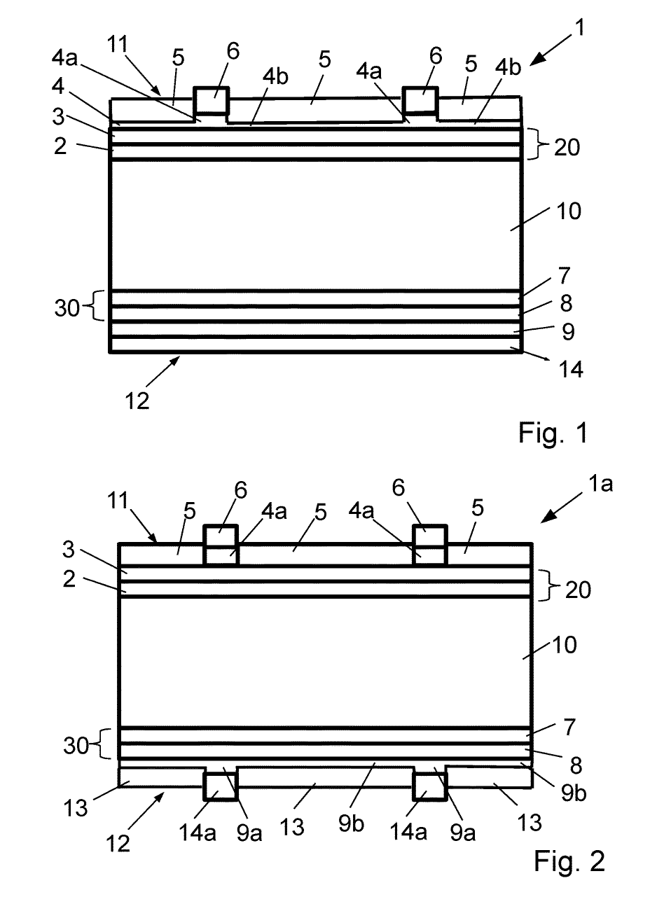

FIG. 1 schematically shows an embodiment of the solar cell of the present invention with locally a reduced thickness of a front side conductive material of the solar cell;

FIG. 2 schematically shows a further embodiment of the solar cell of the present invention wherein the front side conductive material is only situated under front side electrical contacts and wherein a back side conductive material has a locally reduced thickness and wherein a back side electrical contact pattern is provided only on regions of the back side conductive material with non-reduced thickness;

FIG. 3 schematically shows a next embodiment of the solar cell of the present invention being similar to the solar cell of FIG. 2 but having a back side electrical contact layer extending over the whole back surface of the solar cell;

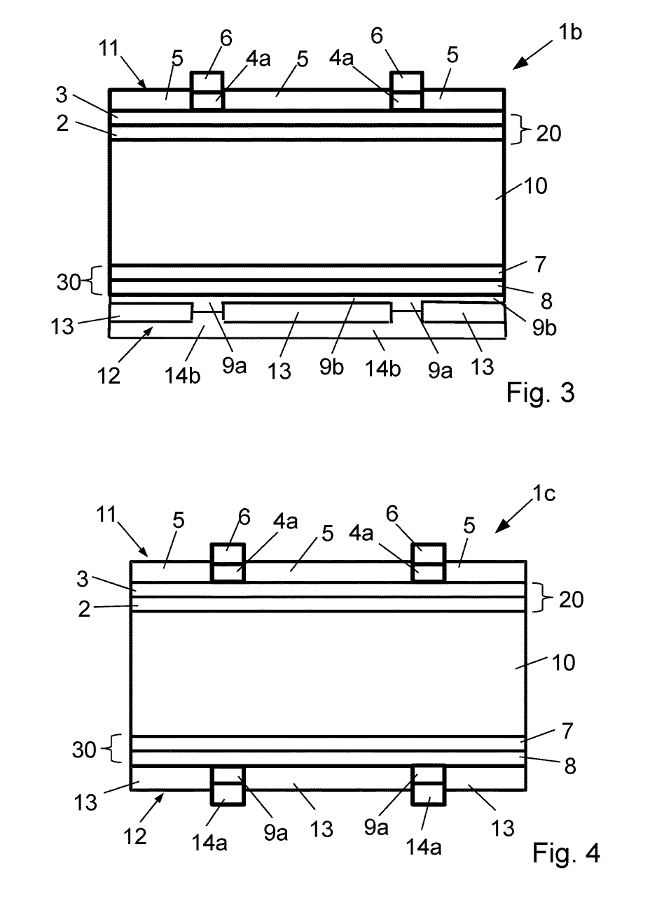

FIG. 4 schematically shows a yet further embodiment of the solar cell of the present invention wherein the front side conductive material is only situated under front side electrical contacts and the back side conductive material is only situated under the back side electrical contacts; and

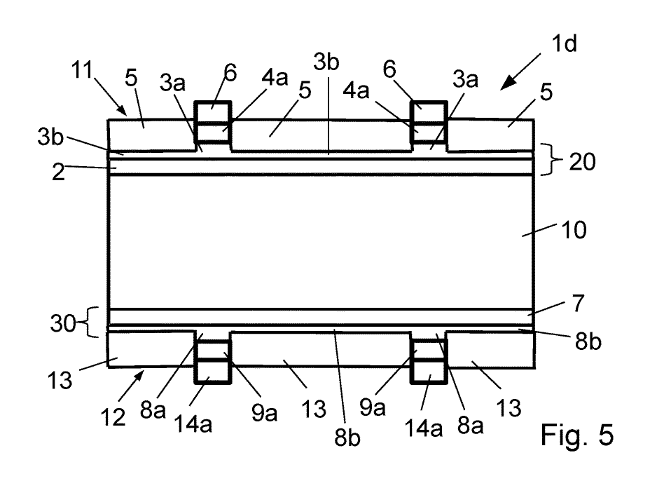

FIG. 5 schematically shows another embodiment of the solar cell of the present invention wherein the thickness of a conductive layer of a front side passivating region as well as the thickness of a conductive layer of a back side passivating region are reduced in regions between and besides the front side electrical contacts and the back side electrical contacts, respectively, in comparison to the regions below the front side electrical contacts and the back side electrical contacts, respectively.

FIG. 1 schematically shows a solar cell 1 in accordance with an embodiment of the present invention. The solar cell 1 has a front side 11 for light incidence and a back side 12 being opposite to the front side 11.

The solar cell 1 comprises a semiconductor substrate 10 of a first conductivity type. In the embodiment shown, the semiconductor substrate 10 is of crystalline n-type silicon. In other non-shown embodiments of the present invention, the semiconductor substrate 10 can also be of a second conductivity type being contrary to the first conductivity type.

On the side of the semiconductor substrate 10 directed to the front side 11, a front side passivating region 20 is formed. The front side passivating region 20 comprises in the embodiment shown a passivating layer 2 and a conductive layer 3 of the first conductivity type. In other non-shown embodiments of the present invention, the front side passivating region 20 can consist of more than two layers, such as more than one passivating layer 2 and/or more than one conductive layer 3. In the embodiment shown, the passivating layer 2 is an intrinsic silicon layer and the conductive layer 3 is an amorphous silicon layer of n-type.

On the front sided surface of the conductive layer 3, a front side contact of the solar cell 1 is formed. The front side contact comprises in the embodiment shown a front side conductive material 4 formed from only one layer and a pattern of front side electrical contacts 6 formed on top of the front side conductive material 4. The front side electrical contacts 6 are designed to extract a photo-generated electrical current up to a non-shown solar cell interconnection. The front side electrical contacts 6 are formed from silver in the embodiment shown. In other embodiments of the present invention, the front side electrical contacts 6 can also be of another material with very good electrical conductivity such as galvanically deposited copper.

In the solar cell 1 of FIG. 1, the front side conductive material 4 is a transparent conductive oxide (TCO) layer, such as an indium tin oxide (ITO) layer. In other non-shown embodiments of the present invention, the front side conductive material 4 can also be of another conductive material having a transparency being much lower than the transparency of an ITO layer, such as a metal or a low cost TCO. The front side conductive material 4 can be applied with different methods, for instance, by a physical vapor deposition, a chemical vapor deposition, an ink-jet method or a screen printing technology. This is possible in the present invention due to the reduced thickness of the front side conductive material 4 in regions 4b between and/or besides the front side electrical contacts 6 in comparison with regions 4a directly below the front side electrical contacts 6. That is, in the regions 4a situated under the front side electrical contacts 6, the front side conductive material 4 is thicker than in the regions 4b besides the regions 4a. In this context, the term “besides” means a region of the same front side conductive material 4 being on the left and/or the right side of the corresponding other region in the horizontal extension of the solar cell 1 if the structure of the solar cell 1 is considered as it is shown schematically in FIG. 1.

Despite of the regions 4a, 4b with different thicknesses, the material of the front side conductive material 4 is one and the same in the regions 4a, 4b. The material of the regions 4a, 4b is formed in one layer forming step, wherein the layer 4 can be formed in a structured manner or can be structured after layer formation. In particular, the different thickness of the front side conductive material 4 can be the result of a homogeneous deposition of the front side conductive material 4, followed by an etch process, such as a wet-chemical etch process, using a mask material, such as a wax or a hot melt, above the front side electrical contacts 6. If the regions 4a, 4b of the front side conductive material 4 are formed with an inkjet method, an etch step after layer formation can be avoided. Alternately, it is also possible to deposit the front side conductive material 4 through a mask.

The surface of the front side conductive material 4 is covered in the regions between and besides the front side electrical contacts with a front side light coupling layer 5. In other non-shown embodiments of the present invention, there can also more than one front side light coupling layers 5 be used. In the example shown, the front side light coupling layer 5 is of silicon nitride. In other embodiments of the present invention, the front side light coupling layer 5 can also be of SiOₓ, SiOₓN_{y}, AlOₓ, AlNₓ, TiOₓ, MgFₓ, a conductive oxide, a layer containing nanoparticles, or of a combination of at least two of the aforesaid materials, including SiNₓ.

On the side of the semiconductor substrate 10 directed to the back side 12 of the solar cell 1, a back side passivating region 30 is formed. The back side passivating region 30 comprises in the embodiment shown a passivating layer 7 and a conductive layer 8 of the second conductivity type. Therefore, the emitter, to say the p-n junction, of the solar cell 1 shown in FIG. 1 is at the back side 12 of the solar cell 1. In other non-shown embodiments of the present invention, the front side passivating region 30 can consist of more than two layers, such as more than one passivation layer 7 and/or more than one conductive layer 8. In the embodiment shown, the passivating layer 7 is an intrinsic silicon layer and the conductive layer 8 is an amorphous silicon layer of p-type.

On the back sided surface of the conductive layer 8, a back side contact of the solar cell 1 is formed. The back side contact comprises in the embodiment shown a back side conductive material 9 and a back side electrical contact 14 formed in the embodiment shown as a continuous layer on top of the back side conductive material 9. The back side conductive material 9 can be a transparent conductive material such as an ITO layer, but can also be of another conductive material having a transparency being lower than the transparency of an ITO layer, such as a metal or a low cost TCO. The back side conductive material 9 can be applied with different methods, for instance, with a physical vapor deposition, by an ink-jet method or by a screen printing technology.

FIG. 2 schematically shows a solar cell 1a in accordance with another embodiment of the present invention. In FIG. 2 as well as in the following figures, same reference signs are used to indicate same or similar details of the present invention. The description of these details, which has already been made above with reference to the embodiment shown in FIG. 1 can also be applied to the corresponding details of the invention in the other embodiments of the invention shown in the following figures.

In comparison to the solar cell 1 of FIG. 1, in the solar cell 1a of FIG. 2 the front side conductive material 4 is absent in the regions 4b between and besides the front side electrical contacts 6 and is only located in the regions 4a below the front side electrical contacts 6.

Furthermore, the solar cell 1a comprises on its back side 12, instead of the continuous back side electrical contact layer 14 of the solar cell 1, a pattern of back side electrical contacts 14a.

The back side conductive material 9 of the solar cell 1a is thinner in regions 9b between and besides the back side electrical contacts 14a than in regions 9a below the back side electrical contacts 14a.

The back sided surface of the back side conductive material 9 of the solar cell 1a is covered with a back side light coupling layer 13 between the back side electrical contacts 14a. In other non-shown embodiments of the present invention, there can also be used more than one back side light coupling layers 13. In the example shown, the back side light coupling layer 13 is of silicon nitride. In other embodiments of the present invention, the back side light coupling layer 13 can also be of SiOₓ, SiOₓN_{y}, AlOₓ, AlNₓ, TIOₓ, MgFₓ, a conductive oxide, a layer containing nanoparticles, or of a combination of at least two of the aforesaid materials, including SiNₓ.

A further variation of the present invention is demonstrated in FIG. 3 showing a solar cell 1b being similar to the solar cell 1a of FIG. 2. In contrast to the solar cell 1a, the solar cell 1b of FIG. 3 comprises a back side contact layer 14b extending at least partially over the back surface of the solar cell 1b. That is, the back side electrical contact 14b is applied also between locally thicker regions 9a of the back side conductive material 9 and extends also over the back side light coupling layer 13. This gives in this variation of the invention an improved reflectivity at the back side 12 of the solar cell 1b and will hence to improve the efficiency of the solar cell 1b.

FIG. 4 schematically shows a solar cell 1c in accordance with a further embodiment of the present invention.

In the solar cell 1c, the front side conductive material 4 is absent in the regions 4b between and besides the front side electrical contacts 6 and is only located in the regions 4a below the front side electrical contacts 6. In the same way, the back side conductive material 9 is absent in the regions 9b between and besides the back side electrical contacts 14a and is only located in the regions 9a below the back side electrical contacts 14a.

FIG. 5 schematically shows a solar cell 1d in accordance with yet another embodiment of the present invention.

As in the solar cell 1c of FIG. 4, in the solar cell 1d the front side conductive material 4 is absent in the regions 4b between and besides the front side electrical contacts 6 and is only located in the regions 4a below the front side electrical contacts 6. In the same way, the back side conductive material 9 is absent in the regions 9b between and besides the back side electrical contacts 14a and is only located in the regions 9a below the back side electrical contacts 14a.

Moreover, the conductive layer 3 on the front side 11 of the solar cell 1d is thinner in regions 3b between and besides the front side electrical contacts 6 than in regions 3a below the front side electrical contacts 6. In addition, the at least one conductive layer 8 on the back side 12 of the solar cell 1d is thinner in regions 8b between and besides the back side electrical contacts 14a than in regions 8a below the back side electrical contacts 14a.

1-14. (canceled)

15. A solar cell, comprising:
a front side for light incidence and a back side disposed opposite to said front side;
a crystalline semiconductor substrate being formed of a first conductivity type or being formed of a second conductivity type opposite to the first conductivity type;
a front side passivating region formed by at least one passivating layer and at least one conductive layer of the first conductivity type;
a back side passivating region formed by at least one passivating layer and at least one conductive layer of the second conductivity type;
a front side contact formed by only one front side conductive material and by a pattern of front side electrical contacts formed on top of said front side conductive material, said front side conductive material being thinner in regions disposed at least one of between or besides said front side electrical contacts than in regions disposed below said front side electrical contacts;
at least one front side light coupling layer disposed on said front side; and
a back side contact being opposite to said front side contact and being formed by a back side conductive material and at least one back side electrical contact formed on said back side conductive material.

16. The solar cell according to claim 15, wherein said front side conductive material is only located in said regions disposed below said front side electrical contacts and is absent in said regions disposed at least one of between or besides said front side electrical contacts.

17. The solar cell according to claim 15, which further comprises an emitter of the solar cell disposed at said back side of the solar cell.

18. The solar cell according to claim 15, wherein:
said back side conductive material is only one material and has a locally increased thickness in regions; and
at least one back side light coupling layer is provided only between said regions of increased thickness.

19. The solar cell according to claim 15, wherein said back side conductive material is not provided under said at least one back side light coupling layer.

20. The solar cell according to claim 18, wherein said at least one back side electrical contact includes a pattern of back side electrical contacts, and said back side electrical contacts are provided only on said regions of said back side conductive material with said locally increased thickness.

21. The solar cell according to claim 18, wherein said at least one back side electrical contact includes a back side electrical contact layer extending at least partially over said at least one back side light coupling layer.

22. The solar cell according to claim 18, wherein:
said at least one conductive layer of said front side passivating region is thinner in regions at least one of between or besides said front side electrical contacts than in regions below said front side electrical contacts;
said at least one conductive layer of said back side passivating region is thinner in regions at least one of between or besides said at least one back side electrical contact than in regions below said at least one back side electrical contact; and
said at least one conductive layer of said back side passivating region is thinner in regions at least one of between or besides said regions of locally increased thickness of said back side conductive material than in said regions below said regions of locally increased thickness.

23. The solar cell according to claim 15, wherein said at least one conductive layer of said front side passivating region is thinner in regions at least one of between or besides said front side electrical contacts than in regions below said front side electrical contacts.

24. The solar cell according to claim 15, wherein said at least one conductive layer of said back side passivating region is thinner in regions at least one of between or besides said at least one back side electrical contact than in regions below said at least one back side electrical contact.

25. The solar cell according to claim 18, wherein said at least one conductive layer of said back side passivating region is thinner in regions at least one of between or besides said regions of locally increased thickness of said back side conductive material than in said regions below said regions of locally increased thickness.

26. The solar cell according to claim 15, wherein at least one of said front side electrical contacts or said at least one back side electrical contact is formed of a material including at least one electrical conductive oxide, at least one metal, at least one metallic alloy, and at least one of a conductive compound or a combination of at least two of said conductive materials.

27. The solar cell according to claim 18, wherein at least one of said at least one front side light coupling layer or said at least one back side light coupling layer is formed of a material selected from at least one material of a group of materials consisting of SiNₓ, SiOₓ, SiOₓN_{y}, AlOₓ, AlNₓ, TiOₓ, MgFₓ, a conductive oxide, a layer containing nanoparticles and a combination of at least two of said materials.

28. The solar cell according to claim 15, wherein at least one of said front side conductive material or said back side conductive material is selected from a group of materials consisting of at least one transparent conductive oxide, at least one metal, at least one metal alloy or at least one conductive oxide.

29. The solar cell according to claim 15, wherein at least one of said front side conductive material or said back side conductive material in regions at least one of between or besides at least one of said front side electrical contacts or said at least one back side electrical contact has a thickness between 0 and 150 nm.

30. The solar cell according to claim 15, wherein at least one of said front side conductive material or said back side conductive material in regions at least one of between or besides at least one of said front side electrical contacts or said at least one back side electrical contact has a thickness between 0 and 70 nm.

31. The solar cell according to claim 15, wherein at least one of said front side conductive material or said back side conductive material in regions at least one of between or besides at least one of said front side electrical contacts or said at least one back side electrical contact has a thickness between 0 and 30 nm.
